(19) United States
(12) Patent Application Publication
(10) Pub. No.: US 2025/0258027 A1
(43) Pub. Date: Aug. 14, 2025

(54) NUCLEAR MAGNETIC FLOWMETER

(71) Applicant: KROHNE AG, Basel (CH)

(72) Inventor: Cornelis Johannes HOGENDOORN, Spijk (NL)

(73) Assignee: KROHNE AG, Basel (CH)

(21) Appl. No.: 19/172,517

(22) Filed: Apr. 7, 2025

Related U.S. Application Data
(63) Continuation of application No. PCT/EP2023/077757, filed on Oct. 6, 2023.

(30) Foreign Application Priority Data
Oct. 7, 2022 (DE) 10 2022 126 008.9

(51) Int. Cl. G01F 1/58; G01R 33/24

(52) U.S. Cl. CPC G01F 1/588; G01R 33/24

(57) ABSTRACT

A nuclear magnetic flowmeter with a measuring tube, a measuring device and a controller. The measuring tube has a longitudinal measuring tube axis. The measuring device has a magnetic field generator, an antenna and a longitudinal measuring axis. The magnetic field generator generates a magnetic field extending along the longitudinal measuring axis. The controller is designed to perform nuclear magnetic measurements on a medium in the measuring tube via the antenna. Thereby the mounting and dismounting of the measuring tube is simplified. The measuring device has a receiver for the measuring tube, and the receiver and the measuring tube can be brought together and separated. The measuring device and the measuring tube are connected to one another. The measuring longitudinal axis and the measuring tube longitudinal axis coincide and the controller can perform nuclear magnetic measurements on a medium in the measuring tube via the antenna.

This nonprovisional application is a continuation of International Application No. PCT/EP2023/077757, which was filed on Oct. 6, 2023, and which claims priority to German Patent Application No. 10 2022 126 008.9, which was filed in Germany on Oct. 7, 2022, and which are both herein incorporated by reference.

### BACKGROUND OF THE INVENTION

### Field of the Invention

The invention relates to a nuclear magnetic flowmeter with a measuring tube, a measuring device and a controller.

### Description of the Background Art

In a nuclear magnetic measurement, a medium is first magnetized by a macroscopic magnetic field. Then a precession of atomic nuclei of the medium is influenced in the presence of the macroscopic magnetic field by exciting the atomic nuclei to nuclear magnetic resonances and the nuclear magnetic resonances are evaluated. For this reason, nuclear magnetic measurements are often also referred to as nuclear magnetic resonance measurements or magnetic resonance measurements and the corresponding measuring devices as nuclear magnetic resonance measuring devices or magnetic resonance measuring devices. The excitation takes place via excitation signals and the resonances are contained in reaction signals.

Precession is a property of atomic nuclei of elements that have a nuclear spin. One such element is hydrogen, for example. The nuclear spin can be understood as an angular momentum describable by a vector and, correspondingly, the magnetic moment caused by the nuclear spin can also be described by a vector parallel to the vector of the angular momentum. The presence of the macroscopic magnetic field causes an excess of atomic nuclei with magnetic moments in the medium that are aligned parallel to the macroscopic magnetic field, whereby the medium has a macroscopic magnetization that can be described in its entirety by a vector. In the presence of the macroscopic magnetic field, the vector of the magnetic moment of an atomic nucleus precesses around the vector of the magnetic field at the location of the atomic nucleus. This is the precession property.

An excitation signal always has at least one electromagnetic high-frequency pulse. For example, an excitation signal has an activation pulse and at least one refocusing pulse. An activation pulse causes a nuclear magnetic resonance in the form of a macroscopic magnetization of the medium that is transverse to the vector of the magnetic field and rotates around the vector of the macroscopic magnetic field. The rotating transversal macroscopic magnetization can be detected as a reaction signal in the form of a free induction decay and/or after refocusing as an echo signal. Thus, a response signal has a free induction decay and/or at least one echo signal. Refocusing of the rotating transverse magnetization is necessary if a relationship between the phases of the precession of the individual magnetic moments of the atomic nuclei that initially exists after the activation pulse is disturbed, for example by inhomogeneities in the macroscopic magnetic field. Refocusing is achieved by a refocusing pulse, which restores the relationship between the phases.

The medium has one or more phases. To determine information about the individual phases, atomic nuclei of the individual phases must be excitable to distinguishable nuclear magnetic resonances. For example, nuclear magnetic resonances differ from each other if longitudinal relaxations of the individual phases have different longitudinal relaxation time constants. Since the multiphase medium extracted from oil wells essentially has crude oil and salt water as liquid phases and natural gas as the gaseous phase, the atomic nuclei of all phases have hydrogen atom nuclei and the phases crude oil and salt water in particular are usually characterized by different longitudinal relaxation time constants, nuclear magnetic measuring devices are well suited for determining information from media extracted from oil wells. In principle, nuclear magnetic measuring devices are suitable for media whose phases have hydrogen nuclei.

The nuclear magnetic flowmeter is designed to perform nuclear magnetic measurements on a medium in the measuring tube. A nuclear magnetic measurement provides at least one piece of information about the medium. Such information is, for example, a property or a flow rate of the medium or a proportion of a phase in the medium if it is a multiphase medium. A nuclear magnetic measurement includes, for example, determining a longitudinal and/or a transverse relaxation time constant and/or a chemical shift.

In particular, the controller is designed to generate excitation signals for the medium and to evaluate the reaction signals caused by the excitation signals in the medium. The antenna device is designed to radiate the excitation signals into the medium in the measuring tube and to receive the reaction signals. The magnetic field generator is designed to generate a magnetic field in the medium, which is located in the measuring tube. It is a macroscopic magnetic field. The longitudinal axis of the measuring tube and the longitudinal axis of the measuring tube usually coincide. The measuring tube is made of a material that is sufficiently transparent for the magnetic field, the excitation signals and the reaction signals.

During operation of the nuclear magnetic flowmeter, a medium is in the measuring tube. For example, the medium flows through the measuring tube, wherein the direction of flow of the medium is along the longitudinal measuring tube axis. However, the medium can also stand still in the measuring tube. The medium in the measuring tube is magnetized by the magnetic field generated by the magnetic field generator. The controller performs nuclear magnetic measurements on the magnetized medium in the measuring tube in the magnetic field using the antenna device. For this purpose, nuclear magnetic excitation signals are generated by the controller, transmitted to the antenna device, radiated into the medium by the antenna device, reaction signals caused by the excitation signals in the medium are received by the antenna device and transmitted to the controller. The reaction signals are evaluated by the controller.

In nuclear magnetic flowmeters of the type described in the prior art, the measuring tube is connected to the rest of the nuclear magnetic flowmeter in such a way that it is not possible to simply replace the measuring tube. Rather, extensive work on the nuclear magnetic flowmeter, and often on the measuring tube itself, is necessary in order to install or remove the measuring tube.

### SUMMARY OF THE INVENTION

It is therefore an object of the present invention to provide a nuclear magnetic flowmeter, in which the installation and removal of the measuring tube is simplified.

The measuring tube has a longitudinal measuring tube axis. The measuring device has a magnetic field generator, an antenna device and a longitudinal measuring axis. The magnetic field generator is designed to generate a magnetic field extending along the longitudinal measuring tube axis. The controller is designed to perform nuclear magnetic measurements on a medium in the measuring tube using the antenna device.

The nuclear magnetic flowmeter according to the invention has a receiving device for the measuring tube. The receiving device and the measuring tube can be brought together and separated. When the receiving device and the measuring tube are brought together, the measuring device and the measuring tube can be connected to and disconnected from each other by the receiving device. When the measuring device and the measuring tube are connected to one another, the longitudinal axis of the measuring device and the longitudinal axis of the measuring tube coincide and the controller can perform nuclear magnetic measurements on the medium in the measuring tube using the antenna device.

The receiving device thus has connectors that connect the receiving device and the measuring tube to each other so that the measuring tube is fixed and aligned in the rest of the nuclear magnetic flowmeter. It is aligned when the measuring axis and the longitudinal measuring tube axis coincide. To connect and disconnect the connectors, it is only necessary to work on the connectors. No further work is therefore necessary on the nuclear magnetic flowmeter. The nuclear magnetic flowmeter is modular, wherein the measuring tube is one module and the rest of the nuclear magnetic flowmeter is another module.

The nuclear magnetic flowmeter according to the invention is advantageous because the measuring tube can be connected and disconnected from the rest of the nuclear magnetic flowmeter in a simple manner.

This also makes it suitable for applications in which the measuring tube is already mounted in a system, as the measuring tube does not have to be dismantled to mount the rest of the nuclear magnetic flowmeter, but can be assembled with the measuring tube by simply attaching it. In many applications, dismantling the measuring tube from the system also involves a great deal of effort, as there are strict requirements in terms of hygiene, purity and safety with regard to the medium in the measuring tube.

Furthermore, the nuclear magnetic flowmeter is also suitable for applications in which different media are to be measured and contamination of one medium by another medium is to be avoided. Contamination is avoided by using a measuring tube for each individual medium. Such applications are often found in life sciences, biotechnology and the medical industry. Such measuring tubes are also referred to as disposable measuring tubes.

In addition to nuclear magnetic flowmeters, ultrasonic, Coriolis and electromagnetic flowmeters are also known from the state of the art. What the listed types of flowmeters have in common is that each has a measuring tube. It has been shown that the measuring accuracy of ultrasonic, Coriolis and electromagnetic flowmeters decreases with a decreasing inner diameter of the measuring tube, whereas this effect does not occur with nuclear magnetic flowmeters. Therefore, in one design of the nuclear magnetic flowmeter, it is provided that an inner diameter of the measuring tube is smaller than 9 mm, preferably smaller than 6 mm and particularly preferably smaller than 3 mm.

The measuring tube and the receiving device can be brought together and separated. The bringing together and separating, in short the assembly, can be carried out in various ways.

In an example of the assembly, the receiving device and the measuring tube can be brought together and separated by moving them relative to each other along a direction perpendicular to the longitudinal axis of the measuring tube. For this purpose, the receiving device usually has a lateral opening through which the measuring tube fits. This design is particularly advantageous for a measuring tube that is already mounted in a system, as the rest of the nuclear magnetic flowmeter can be easily attached and removed. This attachment is also referred to as “clamp on”. A nuclear magnetic flowmeter according to this design is also referred to as a clamp-on flowmeter.

In an example of the assembly, the receiving device and the measuring tube can be brought together and separated by a movement relative to each other along a direction parallel to the longitudinal axis of the measurement. For this purpose, the receiving device usually has an opening at the front through which the measuring tube fits.

During operation of the nuclear magnetic flowmeter, the magnetic field generator generates the magnetic field which magnetizes the medium in the measuring tube and in which the nuclear magnetic measurements are performed on the medium. In one design, the magnetic field generator is designed to generate the magnetic field with a direction parallel to the longitudinal measuring tube axis. Consequently, the magnetic field then extends along the longitudinal measuring axis and has the direction parallel to the longitudinal measuring axis.

In an example, the magnetic field generator can have a coil arranged on the measuring tube to generate the magnetic field. Preferably, the coil is a cylindrical coil arranged around the measuring tube. The magnetic field generator is designed to supply electricity to the coil so that it generates the magnetic field during operation. The cylindrical coil arranged around the measuring tube is wound around the measuring tube, for example. Furthermore, the measuring tube and the receiving device preferably have an electrical plug connection for the electrical supply of the coil by the magnetic field generator. In particular, the electrical plug connection is designed in such a way that it is connected when the measuring device and the measuring tube are brought together and disconnected when the measuring device and the measuring tube are separated.

The magnetic field generator can be designed to generate the magnetic field with a direction perpendicular to the longitudinal measurement axis. Consequently, the magnetic field then extends along the longitudinal measuring axis and has the direction perpendicular to the longitudinal measuring axis.

The magnetic field generator can have permanent magnets which generate the magnetic field. The generation of the magnetic field by permanent magnets is advantageous as they do not require any electrical current and ensure compact dimensions of the nuclear magnetic flowmeter.

In an example of the nuclear magnetic flowmeter with permanent magnets, the magnetic field generator can have a yoke. The yoke arranges the permanent magnets and guides a magnetic flux of the magnetic field. The arrangement of the permanent magnets by the yoke also means that the yoke fixes them in place.

The yoke can have an opening along the longitudinal measuring tube axis. This opening can be designed in such a way that the receiving device and the measuring tube can be brought together and separated by a movement relative to each other along the direction perpendicular to the longitudinal measuring tube axis. However, if the yoke does not have an opening, then a combination with the design in which the receiving device and the measuring tube can be brought together and separated by a movement relative to each other along the direction parallel to the longitudinal axis of the measuring tube is advantageous.

The yoke can have a first partial yoke, a second partial yoke and a hinge. The first partial yoke and the second partial yoke are pivotably connected to each other by the hinge and can be pivoted into an open state and a closed state. In the open state, the receiving device and the measuring tube can be brought together and separated, and in the closed state, the yoke guides the magnetic flux of the magnetic field. This design is preferably combined with the clamp-on design described above.

The permanent magnets can be arranged either in the first partial yoke and in the second partial yoke or only in the first partial yoke.

The magnetic field generator can have a support for permanent magnets and the support arranges the permanent magnets in a Halbach array. The Halbach array efficiently guides the magnetic flux of the magnetic field. It is particularly preferable for the support to be formed like the yoke described above.

The antenna device can be arranged on the measuring tube. Consequently, the receiving device has a connection device for the electrical connection of the antenna device. When the measuring tube with the antenna device and the receiving device are brought together, the antenna device and the connection device are electrically connected to each other. If the measuring tube and the receiving device are separated, then the antenna device and the connection device are also electrically separated. The connection device and the measuring tube have a corresponding electrical plug connection. Due to the arrangement on the measuring tube, the antenna device is closer to the medium than if it were arranged on the rest of the nuclear magnetic measuring device. The smaller distance between the antenna device and the medium improves the signal-to-noise ratio, which also improves the quality of the nuclear magnetic measurements.

A data carrier can be arranged on the measuring tube. Calibration data of the antenna device is stored on the data carrier. The data carrier can be, for example, an RFID tag, a barcode or a QR code. The controller is designed to perform nuclear magnetic measurements using calibration data. Preferably, the controller is also designed to read the calibration data from the data carrier when the receiving device and the measuring tube are brought together. This design is preferably combined with disposable measuring tubes.

The antenna device can be designed to radiate the excitation signals into the medium in the measuring tube and to receive the reaction signals from the medium. The reaction signals are caused by the excitation signals in the medium. For this purpose, in one design of the nuclear magnetic flowmeter, the antenna device has at least one coil for transmitting the excitation signals and/or for receiving the reaction signals. Accordingly, the antenna device has, for example, at least one coil for transmitting the excitation signals and for receiving the reaction signals or at least one coil for transmitting the excitation signals and at least one coil for receiving the receive signals.

The at least one coil of the nuclear magnetic flowmeter can be designed in various ways.

In an example of the at least one coil, this can be a surface coil. If the at least one coil is a surface coil, then a combination with a design in which the receiving device and the measuring tube can be brought together and separated by a movement relative to one another along the direction perpendicular to the measuring tube axis is advantageous, since the at least one coil provides the space required for this. The at least one surface coil can be designed in different ways.

In an example of the at least one surface coil, this can be a Helmholtz coil. Preferably, a conductor of the Helmholtz coil is arranged in a round or rectangular shape. Preferably, the conductor has a single turn.

In an example of the at least one surface coil, this can be a spiral coil. Preferably, one conductor of the spiral coil can be arranged in a round or rectangular shape.

In an example of the at least one surface coil, this can be a stripline. The stripline has at least one strip. Preferably, the at least one strip is a conductor or a trace.

In an example of the at least one coil, this can be a volume coil. Preferably, the volume coil can be a saddle coil, a birdcage coil or a cylindrical coil. Compared to surface coils, volume coils have a higher efficiency when irradiating the excitation signals and receiving the reaction signals. If the at least one coil is a volume coil, then a combination with a design in which the receiving device and the measuring tube can be brought together and separated by a movement relative to each other along the direction parallel to the longitudinal measuring axis is advantageous. This is because with a saddle coil, compared to a surface coil, a lateral opening in the receiving device, which enables the receiving device and the measuring tube to be brought together and separated by a movement relative to each other along the direction perpendicular to the longitudinal measuring tube axis, is more difficult to implement.

The antenna device can have a further coil. The coil and the further coil can be arranged opposite each other or stacked on top of each other in relation to the measuring tube. The further coil is preferably designed like the coil.

The at least one coil can therefore be either a surface coil or a volume coil. If there is more than one coil, these can be either all surface coils or all volume coils or a combination of surface and volume coils.

The invention also relates to a nuclear magnetic flowmeter with a measuring tube, an antenna device, a magnetic field generator and a controller.

The measuring tube can have a premagnetization section and a measuring section. The antenna device can be arranged in the measuring section. The magnetic field generator can be designed to generate a magnetic field along a magnetic field path. The premagnetization section and the measuring section are arranged completely in the magnetic field section. The controller can be designed to perform nuclear magnetic measurements on a medium in the measuring section of the measuring tube using the antenna device.

A quality of nuclear magnetic measurements on a medium in the measuring tube correlates with a magnetization of the medium in the measuring tube. Thus, a signal-to-noise ratio of the nuclear magnetic measurements correlates with the magnetization of the medium. A higher magnetization of the medium results in a higher signal-to-noise ratio for the measurements and consequently a higher quality of the measurements.

It is known in the conventional art to increase the magnetization in two different ways.

According to the first type, the magnetic field strength is increased. The magnetic field is generated in the magnetic field generator either by an electromagnet or by permanent magnets. In both cases, increasing the magnetic field strength results in a larger volume and higher costs for the nuclear magnetic flowmeter. With the electromagnet, there are also higher energy costs.

According to the second type, the premagnetization section is extended. However, this also means an extension of the nuclear magnetic flowmeter and thus a larger volume and higher costs.

An object of the present invention is therefore the specification of a nuclear magnetic flowmeter of the type described, in which the magnetization of the medium is increased, but the volume and cost are lower than known in the convnetional art.

The object is achieved on the one hand by a nuclear magnetic flowmeter in that a length of the measuring tube in the premagnetization section is greater than a length of the premagnetization section.

In an example of the nuclear magnetic flowmeter, the measuring tube has at least one loop in the premagnetization section. A loop of the measuring tube causes a medium flowing in the measuring tube to have one direction before the loop and a direction opposite to the direction after the loop.

In a further design, the measuring tube can have at least one bend in the premagnetization section.

The nuclear magnetic flowmeter can be designed and further developed in a variety of ways.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a first example of a nuclear magnetic flowmeter in a first state,

FIG. 2 shows the first example in a second state,

FIG. 3 shows a second example of a nuclear magnetic flowmeter in a first state,

FIG. 4 shows the second example in a second state,

FIG. 5 shows a third example of a nuclear magnetic flowmeter with a yoke,

FIG. 6 shows a fourth example of a nuclear magnetic flowmeter with a yoke with an opening,

FIG. 7 shows a fifth example of a nuclear magnetic flowmeter with a two-part yoke,

FIG. 8 shows a sixth example of a nuclear magnetic flowmeter with a two-part yoke,

FIG. 9 shows a seventh example of a nuclear magnetic flowmeter with a support for permanent magnets,

FIG. 10 shows a first example of an antenna device,

FIG. 11 shows a second example of an antenna device,

FIG. 12 shows a third example of an antenna device,

FIG. 13 shows a fourth example of an antenna device,

FIG. 14 shows a fifth example of an antenna device,

FIG. 15 shows a sixth example of an antenna device,

FIG. 16 shows a seventh example of an antenna device,

FIG. 17 shows an eighth example of an antenna device,

FIG. 18 shows a ninth example of an antenna device,

FIG. 19 shows a first example of a measuring tube,

FIG. 20 shows a second example of a measuring tube, and

FIG. 21 shows a third example of a measuring tube.

### DETAILED DESCRIPTION

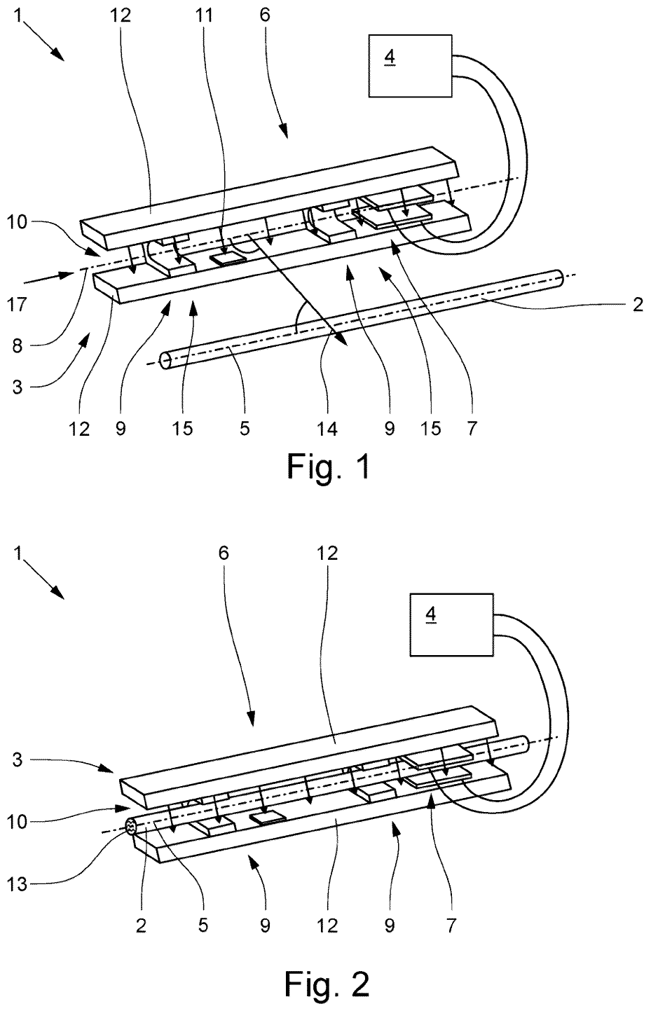

FIG. 1 shows a first example of a nuclear magnetic flowmeter 1 in a perspective view in a first state. The nuclear magnetic flowmeter 1 has a measuring tube 2, a measuring device 3 and a controller 4. The measuring tube 2 has a longitudinal measuring tube axis 5 and an inner diameter of 3 mm.

The measuring device 3 has a magnetic field generator 6, an antenna device 7, a longitudinal measuring axis 8 and a receiving device 9. The receiving device is divided into two parts. The magnetic field generator 6 is designed to generate a magnetic field 10 with a direction 11 perpendicular to the longitudinal measuring axis 8 and extending along the longitudinal measuring axis 8. It has permanent magnets 12 for generating the magnetic field 10. The controller 4 is designed to perform nuclear magnetic measurements on a medium 13 in the measuring tube 2 using the antenna device 7.

The receiving device 9 and the measuring tube 2 can be brought together and separated. The receiving device 9 and the measuring tube 2 can be brought together and separated by a movement relative to each other along a direction 14 perpendicular to the longitudinal measuring tube axis 5. For this purpose, the receiving device 9 has a lateral opening 15 through which the measuring tube 2 fits. In this example, the measuring tube 2 is already mounted in a system and the rest of the nuclear magnetic flowmeter 1 can be attached to the measuring tube 2 and removed from it. This is therefore a clamp-on flowmeter.

The measuring device 3 and the measuring tube 2, when the receiving device 9 and the measuring tube 2 are brought together, can be connected and disconnected by the receiving device 9. When the measuring device 3 and the measuring tube 2 are connected to each other, the longitudinal measuring axis 8 and the longitudinal measuring tube axis 5 coincide and the controller 4 can carry out nuclear magnetic measurements on the medium 13 in the measuring tube 2 using the antenna device 7.

The first state of the nuclear magnetic flowmeter 1 is characterized in that it is not in operation and is disconnected from the measuring tube 2. FIG. 2 shows the nuclear magnetic flowmeter 1 in a second state. This is characterized in that it is mounted on the measuring tube 2 during operation. The medium 13 is made to flow through the measuring tube 2 and the controller 4 performs nuclear magnetic measurements on the medium 13 in the measuring tube 2 using the antenna device 7.

In the following, further examples of nuclear magnetic flowmeters and components such as antenna devices and measuring tubes are presented. However, essentially only differences between the examples are described. In all other respects, the same applies.

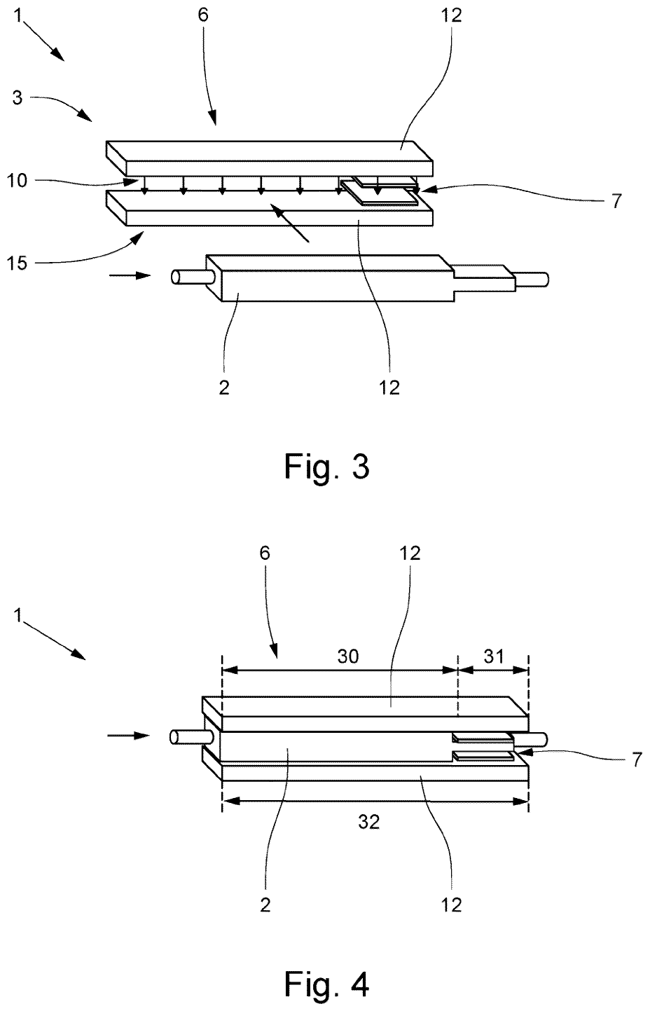

FIG. 3 shows a second example of a nuclear magnetic flowmeter 1 in a perspective view in a first state and FIG. 4 in a second state.

The second example differs from the first example in that the remaining nuclear magnetic flowmeter 1 cannot be placed on the measuring tube 2 and removed therefrom, but that the measuring tube 2 can be inserted into the remaining nuclear magnetic flowmeter 1 and removed therefrom. The nuclear magnetic flowmeter 1 is therefore fixed and the measuring tube 2 is movable. The measuring tube 2 is, for example, a disposable measuring tube.

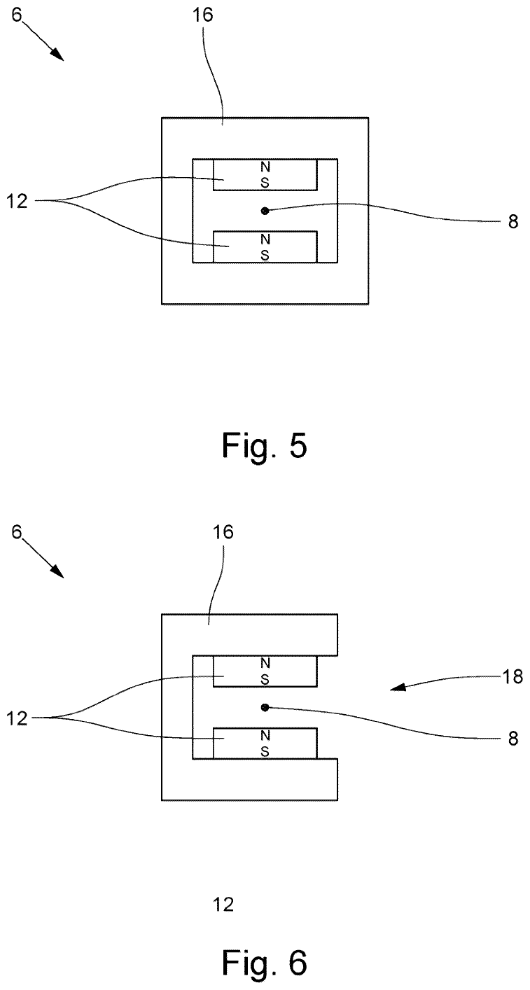

FIG. 5 shows a third example of a nuclear magnetic flowmeter 1, in which the magnetic field generator 6 also has a yoke 16. The yoke 16 arranges the permanent magnets 12 and guides a magnetic flux of the magnetic field 10. Since the yoke 16 is closed all around, the receiving device 9 and the measuring tube 2 can be brought together and separated by a movement relative to each other along a direction 17 parallel to the longitudinal measuring axis 8.

FIG. 6 shows a fourth example of a nuclear magnetic flowmeter 1, in which the magnetic field generator 6 also has a yoke 16. In this example, however, the yoke 16 has an opening 18 along the longitudinal measuring axis 8 compared to the third example. As a result, the receiving device 9 and the measuring tube 2 can be brought together and separated by a movement relative to each other along the direction 14 perpendicular to the longitudinal measuring tube axis 5.

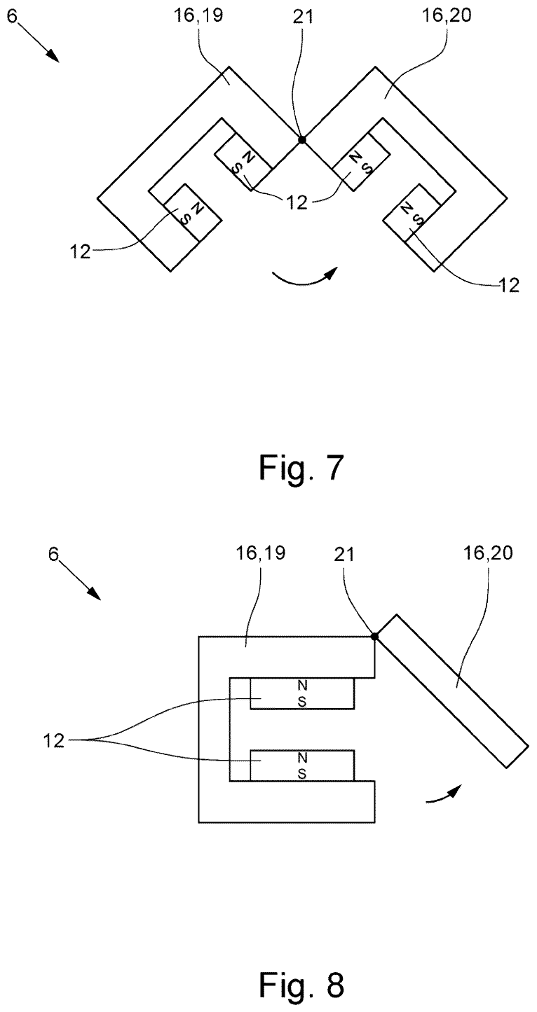

FIG. 7 shows a fifth example of a nuclear magnetic flowmeter 1, in which the magnetic field generator 6 has a yoke 16, which has a first partial yoke 19, a second partial yoke 20 and a hinge 21. Consequently, the yoke 16 is divided into the first partial yoke 19 and the second partial yoke 20. The first partial yoke 19 and the second partial yoke 20 are pivotably connected to one another by the hinge 21 and can be pivoted into an open state and a closed state. FIG. 7 shows the yoke 16 in the open state. In the open state, the receiving device 9 and the measuring tube 2 can be brought together and separated, and in the closed state, the yoke 16 guides the magnetic flux of the magnetic field 10. The permanent magnets 12 are arranged in the first partial yoke 19 and in the second partial yoke 20.

FIG. 8 shows a sixth example of a nuclear magnetic flowmeter 1. In this example, the magnetic field generator 6 also has a yoke 16, which has a first partial yoke 19, a second partial yoke 20 and a hinge 21. In contrast to the fifth example, however, the permanent magnets 12 are arranged only in the first partial yoke 19. FIG. 8 shows the yoke 16 in the open state.

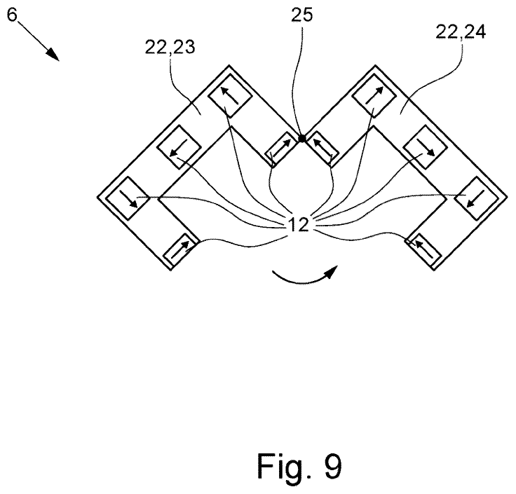

FIG. 9 shows a seventh example of a nuclear magnetic flowmeter 1. The magnetic field generator 6 has a support 22 in which the permanent magnets 12 are arranged in a Halbach array. In this example, the support 22 is additionally designed similarly to the yoke 16. Namely, the support 22 has a first partial support 23, a second partial support 24 and a hinge 25. The first partial support 23 and the second partial support 24 are pivotably connected to one another by the hinge 25 and can be pivoted into an open state and a closed state. In the open state, the receiving device 9 and the measuring tube 2 can be brought together and separated, and in the closed state, the permanent magnets 12 form the Halbach array. FIG. 9 shows the support 22 in the open state.

Examples of an antenna device 7 of a nuclear magnetic flowmeter 1 are presented below. The examples of the antenna device 7 have surface coils and/or volume coils. Initially, examples are described which have a first coil 26 and a second coil 27, both of which are designed as surface coils.

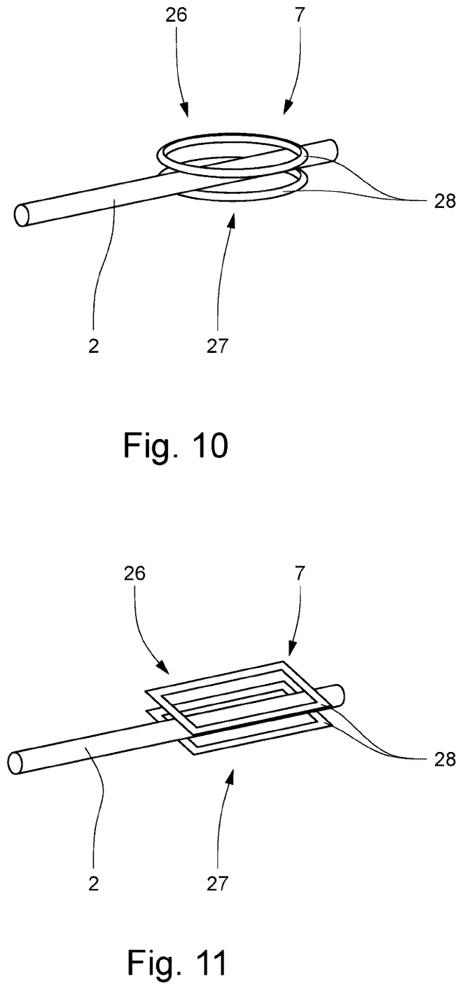

FIG. 10 shows a first example of an antenna device 7 with a first coil 26 and a second coil 27, each of which is a surface coil, namely a Helmholtz coil. The first coil 26 and the second coil 27 are arranged opposite each other with respect to a measuring tube 2. In this example, a conductor 28 of each of the two coils 26, 27 is arranged in a round shape.

FIG. 11 shows a second example of an antenna device 7. It differs from the first example in that a conductor 28 of each of the two coils 26, 27 is arranged in an angular shape.

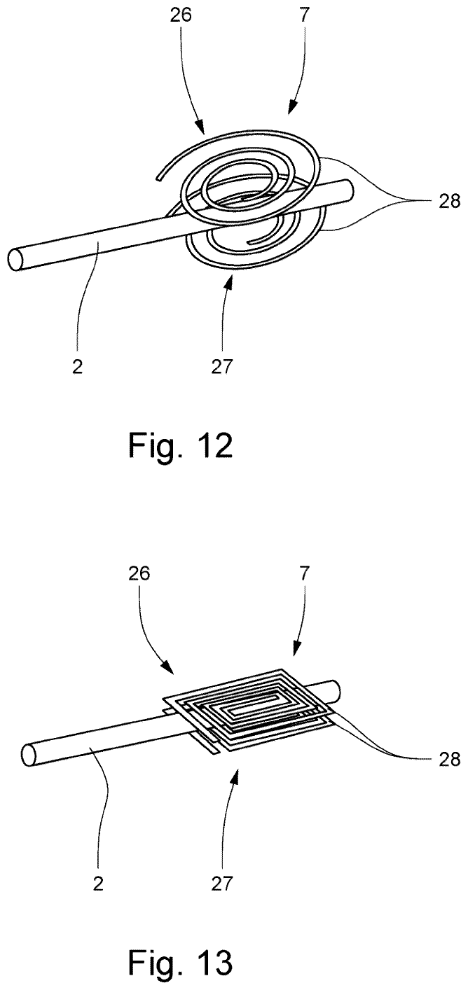

FIG. 12 shows a third example of an antenna device 7 with a first coil 26 and a second coil 27, each of which is a surface coil, namely a spiral coil. The first coil 26 and the second coil 27 are arranged opposite each other with respect to a measuring tube 2. In this example, a conductor 28 of each of the two coils 26, 27 is arranged in a round shape.

FIG. 13 shows a fourth example of an antenna device 7. It differs from the third example in that a conductor 28 of each of the two coils 26, 27 is arranged in an angular shape.

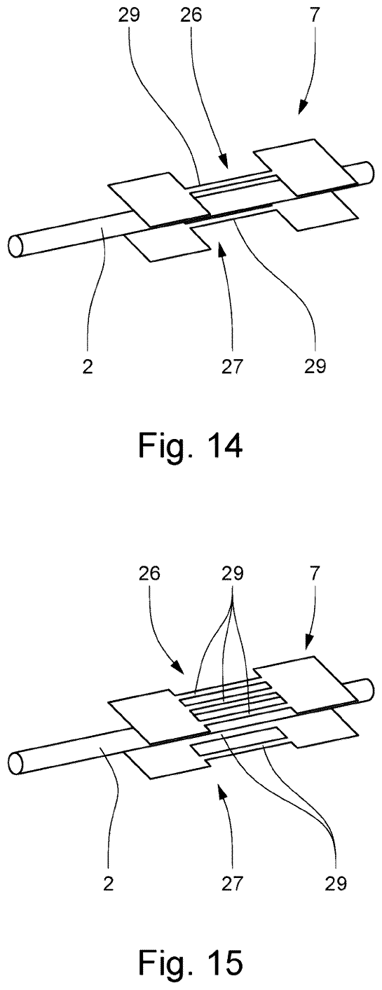

FIG. 14 shows a fifth example of an antenna device 7 with a first coil 26 and a second coil 27, each of which is a surface coil, namely a stripline with a strip 29. The first coil 26 and the second coil 27 are arranged opposite each other with respect to a measuring tube 2. The strip 29 is a trace.

FIG. 15 shows a sixth example of an antenna device 7, which differs from the fifth example in that the striplines each have three strips 29.

Following the examples of an antenna device 7 comprising surface coils, examples comprising one or two volume coils are described below.

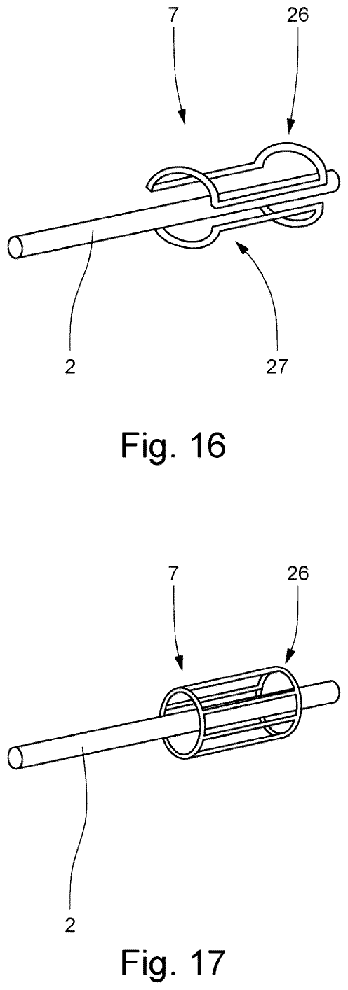

FIG. 16 shows a seventh example of an antenna device 7 with a first coil 26 and a second coil 27, each of which is a volume coil, namely a saddle coil. The first coil 26 and the second coil 27 are arranged opposite each other with respect to a measuring tube 2.

FIG. 17 shows an eighth example of an antenna device 7 with a first coil 26, which is a volume coil, namely a birdcage coil.

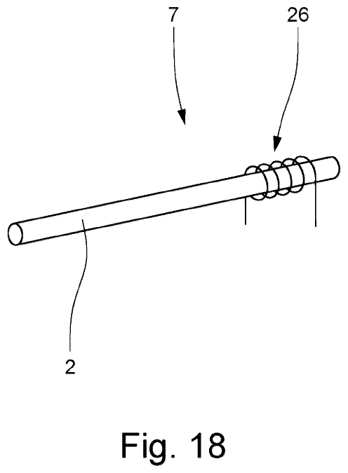

FIG. 18 shows a ninth example of an antenna device 7 with a first coil 26, which is a volume coil, namely a cylindrical coil.

In the following, examples for a measuring tube 2 of a nuclear magnetic flowmeter 1 are presented, which increase a magnetization of a medium 13.

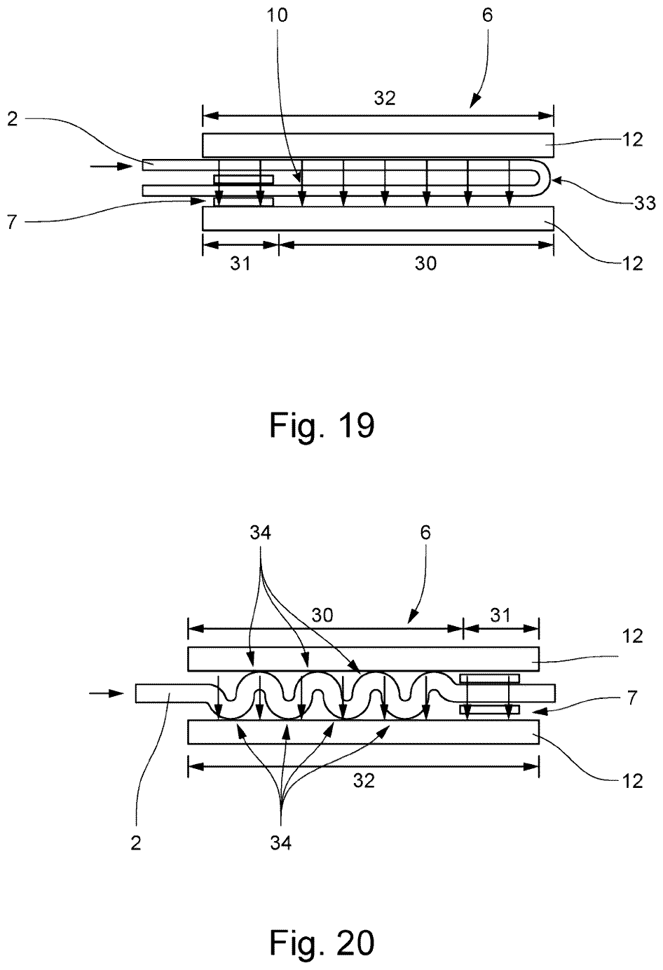

FIG. 19 shows a first example of a measuring tube 2 of a nuclear magnetic flowmeter 1. The nuclear magnetic flowmeter 1 also has an antenna device 7, a magnetic field generator 6 and a controller 4.

The measuring tube 2 has a premagnetizing section 30 and a measuring section 31 and the antenna device 7 is arranged in the measuring section 31. The magnetic field generator 6 is designed to generate a magnetic field 10 along a magnetic field section 32, and the premagnetizing section 30 and the measuring section 31 are arranged completely in the magnetic field section 32. The controller 4 is designed to perform nuclear magnetic measurements on a medium 13 in the measuring section 31 of the measuring tube 2 using the antenna device 7.

The measuring tube 2 has a loop 33 in the premagnetizing section 30, whereby a length of the measuring tube 2 in the premagnetizing section 30 is greater than a length of the premagnetizing section 30.

FIG. 20 shows a second example of a measuring tube 2, which differs from that in the first example in that the measuring tube 2 has a plurality of bends 34 in the premagnetization section 30, whereby a length of the measuring tube 2 in the premagnetization section 30 is greater than a length of the premagnetization section 30.

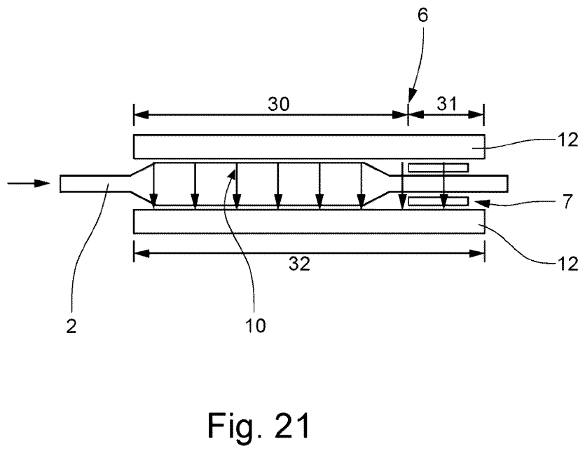

FIG. 21 shows a third example of a measuring tube 2. This differs from the two previous examples in that the measuring tube 2 has a larger cross-sectional area in the premagnetization section 30 than in the measuring section 31. The measuring tube 2 of the second example of a nuclear magnetic flowmeter, see FIGS. 3 and 4, is designed in the same way.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A nuclear magnetic flowmeter comprising:
a measuring tube having a longitudinal measuring tube axis;
a measuring device having a magnetic field generator, an antenna, and a longitudinal measuring axis; and
a controller,
wherein the magnetic field generator generates a magnetic field extending along the longitudinal measurement axis,
wherein the controller performs nuclear magnetic measurements on a medium in the measuring tube using the antenna,
wherein the measuring device has a receiver for the measuring tube,
wherein the receiver and the measuring tube are adapted to be brought together and separated,
wherein the measuring device and the measuring tube, when the receiver and the measuring tube are brought together, are adapted to be connected to and disconnected from one another by the receiver, and
wherein, when the measuring device and the measuring tube are connected to one another, the longitudinal measuring axis and the longitudinal measuring tube axis coincide and nuclear magnetic measurements are carried out by the controller on the medium in the measuring tube via the antenna.

2. The nuclear magnetic flowmeter according to claim 1, wherein an inner diameter of the measuring tube is smaller than 9 mm, smaller than 6 mm, or smaller than 3 mm.

3. The nuclear magnetic flowmeter according to claim 1, wherein the receiver and the measuring tube are adapted to be brought together and separated by a movement relative to each other along a direction substantially perpendicular to the longitudinal measuring tube axis.

4. The nuclear magnetic flowmeter according to claim 1, wherein the receiver and the measuring tube are adapted to be brought together and separated by a movement relative to each other along a direction substantially parallel to the longitudinal measuring axis.

5. The nuclear magnetic flowmeter according to claim 1, wherein the magnetic field generator generates the magnetic field with a direction substantially parallel to the longitudinal measuring axis, wherein the magnetic field generator has a coil arranged on the measuring tube for generating the magnetic field, and wherein the coil is a cylindrical coil arranged around the measuring tube.

6. The nuclear magnetic flowmeter according to claim 1, wherein the magnetic field generator generates the magnetic field with a direction substantially perpendicular to the longitudinal axis of measurement.

7. The nuclear magnetic flowmeter according to claim 6, wherein the magnetic field generator has permanent magnets for generating the magnetic field.

8. The nuclear magnetic flowmeter according to claim 7, wherein the magnetic field generator comprises a yoke, and wherein the yoke arranges the permanent magnets and guides a magnetic flux of the magnetic field.

9. The nuclear magnetic flowmeter according to claim 8, wherein the yoke has an opening along the longitudinal measuring axis so that the receiver and the measuring tube are adapted to be brought together and separated by a movement relative to one another along the direction substantially perpendicular to the longitudinal measuring tube axis.

10. The nuclear magnetic flowmeter according to claim 8, wherein the yoke has a first partial yoke, a second partial yoke, and a hinge, and wherein the first partial yoke and the second partial yoke are pivotably connected to one another by the hinge and are adapted to be pivoted into an open state and a closed state, wherein in the open state, the receiver and the measuring tube are adapted to be brought together and separated, wherein in the closed state, the yoke guides the magnetic flux of the magnetic field, and wherein the permanent magnets are arranged either in the first partial yoke and in the second partial yoke or only in the first partial yoke.

11. The nuclear magnetic flowmeter according to claim 7, wherein the magnetic field generator has a support for the permanent magnets, and wherein the support arranges the permanent magnets in a Halbach array.

12. The nuclear magnetic flowmeter according to claim 1, wherein the antenna is arranged on the measuring tube, wherein a data carrier is arranged on the measuring tube, wherein calibration data of the antenna are stored on the data carrier, wherein the data carrier is an RFID tag, a bar code or a QR code.

13. The nuclear magnetic flowmeter according to claim 1, wherein the antenna has at least one coil for transmitting excitation signals and/or for receiving response signals caused by the excitation signals.

14. The nuclear magnetic flowmeter according to claim 13, wherein the at least one coil is a surface coil.

15. The nuclear magnetic flowmeter according to claim 14, wherein the at least one coil is a Helmholtz coil, wherein a conductor of the Helmholtz coil is arranged in a round or oval or elliptical or rectangular shape, wherein the conductor has a single turn, or wherein the at least one coil is a spiral coil, and wherein a conductor of the spiral coil is arranged in a round or rectangular shape.

16. The nuclear magnetic flowmeter according to claim 13, wherein the at least one coil is a stripline, wherein the stripline has at least one strip, wherein the at least one strip is a conductor or a trace, or wherein the at least one coil is a volume coil, and wherein the volume coil is a saddle coil, a birdcage coil or a cylindrical coil.

17. The nuclear magnetic flowmeter according to claim 13, wherein the antenna has a further coil and that the coil and the further coil are arranged opposite each other or stacked on top of each other with respect to the measuring tube.

18. A nuclear magnetic flowmeter comprising:
a measuring tube;
an antenna;
a magnetic field generator; and
a controller,
wherein the measuring tube has a premagnetization section and a measuring section,
wherein the antenna is arranged in the measuring section,
wherein the magnetic field generator generates a magnetic field along a magnetic field section,
wherein the premagnetization section and the measuring section are arranged completely in the magnetic field section,
wherein the controller is designed to perform nuclear magnetic measurements on a medium in the measuring section of the measuring tube via the antenna, and
wherein a length of the measuring tube in the premagnetization section is greater than a length of the premagnetization section.

19. The nuclear magnetic flowmeter according to claim 18, wherein the measuring tube has at least one loop in the premagnetization section.

20. The nuclear magnetic flowmeter according to claim 18, wherein the measuring tube has at least one bend in the premagnetization section.
